(19) United States
(12) Patent Application Publication
(10) Pub. No.: US 2003/0123679 A1
(43) Pub. Date: Jul. 3, 2003

(54) In-wall loudspeaker

(76) Inventors: William R. Dudleston, Springfield, IL (US); Troy M. Caldwell, Springfield, IL (US)

Correspondence Address: Robert E. Cannuscio, DRINKER BIDDLE & REATH LLP, One Logan Square, 18th & Cherry Streets, Philadelphia, PA, 19103-6996, US

(21) Appl. No.: 10/335,355

(22) Filed: Dec. 31, 2002

Related U.S. Application Data
(60) Provisional application No. 60/346,192, filed on Jan. 2, 2002.

(51) Int. Cl. H04R 1/02; H05K 5/00

(52) U.S. Cl. 381/87; 381/386; 381/395; 181/150

(57) ABSTRACT

The present invention relates to a loudspeaker system designed to mount into a building's interior wall through an opening between two framing studs. The loudspeaker system includes a speaker enclosure with two opposed side walls. At least one side wall has a slot formed in it. At least one rail is mounted to a framing stud and extends outward from the opening. The enclosure is mounted to the wall by sliding the slot along the rail. Fasteners are used to secure the enclosure to the rail.

### RELATED APPLICATIONS

This application claims benefit of U.S. Provisional Patent Application No. 60/346,192, filed Jan. 2, 2002, which is incorporated herein by reference in its entirety.

### FIELD OF THE INVENTION

The present invention relates to a sound speaker system that is capable of being mounted in walls between the framing studs.

### BACKGROUND OF THE INVENTION

Hi-fidelity sound reproduction equipment is utilized in many households. Historically, high quality, hi-fidelity sound was provided by speakers that were considered additional furniture pieces due to their size. Many households opted to sacrifice the sound quality provided by larger speakers for smaller, less obtrusive speakers. While small speakers are quite able to provide high quality reproduction of the higher frequency ranges, they are not as capable in providing the lower range of frequencies as compared with traditional larger loudspeaker systems.

To address this issue, there has been an increased interest in recent years in mounting speakers directly into a wall. In-wall speakers combine the unobtrusive nature of small speakers with the sound quality of traditional speakers. In recent years, new home construction has included provisions for mounting speakers directly into a wall. For example, speaker wiring is often run behind or through the wall framing studs at the time of construction. Generally, in-wall speakers are retrofitted into wall openings so that they are not damaged by wall finishing. One method of installing speakers into wall openings consists of using a metal chassis or frame that is crimped to attach itself to the dry wall gypsum board. Another method is to use screws with expanding “butterfly” anchoring devices. Both methods are limited in the amount of weight that they can hold. As such, they limit the size of the speaker that can be mounted.

A need exists for an improved in-wall speaker mounting system which addresses the deficiencies of the prior art.

### SUMMARY OF THE INVENTION

The present invention relates to a loudspeaker system designed to be mounted into a building's interior wall through a rough opening between a wall's framing studs. The system attaches the speaker cabinet to the wall using a rail support arrangement. The new system is more structurally sound than prior systems since it does not rely on the dry wall gypsum board for support. As a result, heavier speakers may be used.

The present invention is designed to fit between the standard 14.5″ spacing that exists between the wall framing studs. Support rails are mounted directly to the framing studs and project orthogonal to the framing studs. The rails are designed to slide within slots formed in the loudspeaker cabinet. The guide slots or projecting rails may be lined with a vibration absorbing foam or elastomer material which reduces vibratory transmission between the cabinet and the wall.

The cabinet design is of layered construction including a front baffle or panel which provides a mechanism for mounting the speakers while also including a lip or overhanging edge that conceals the rough drywall opening. The decorative lip overhangs at least one and a half inches on all four sides of the enclosure. Although the speaker cabinet is sized to fit between a conventional 14.5 inch stub spacing, the cabinet could be made for other stud spacings as well. The speaker cabinet body walls are preferably built up by laminating several sections together. The sections can be made of milled (wood, composite) or extruded (polymer) material. These sections are stacked upon one another to form the enclosure's internal cavities and chambers. This method of construction allows the cabinet body to be fabricated with different interior chambers, each having different depths. For example, a cabinet wall may include 4 sections, all four of which define the woof chambers, but only three of which define the walls of the mid-range or tweeter chambers.

The cabinet wall sections divide the interior cavity into separate chambers for the loudspeakers which are preferably substantially acoustically isolated from one another. The loudspeaker assembly may have at least one woofer speaker for providing low frequency sound reproduction, at least one tweeter speaker for providing high frequency sound reproduction, and a midrange speaker for providing middle frequency sound reproduction. A crossover device may also be used for band pass filtering of audio electrical signal transmitted to the loudspeakers. A passive radiator is used to prevent port noise while minimizing necessary woofer excursion. A second-order high pass filter is also included below the pass-band to minimize unnecessary excitation of cabinet structure.

Two apertures are formed in and extend through the front panel. On the back side of the front panel a steel reinforcing plate or bracket with a hold in it is mounted to the panel adjacent to each aperture so that the hole in the plate aligns with the aperture. A wood screw or other fastener is adapted to seat within each aperture to attach the cabinet to one of the rails by threading into the face of the rail pieces. The screw fasteners are preferably isolated from the cabinet walls by incorporating elastomeric grommets or bushings in the hole in the reinforcing plate. This allows the speaker cabinet enclosure to become fixed to the wall framing and pulled tight against the wall covering via the screw tension adjustment, while remaining substantially decoupled vibrationally/acoustically from the wall frame. The screw heads may then be covered by inserting a grill plug into the apertures. A foam gasket may be inserted between the lip of the front panel and the drywall.

The foregoing and other features of the invention and advantages of the present invention will become more apparent in light of the following detailed description of the preferred embodiments, as illustrated in the accompanying figures. As will be realized, the invention is capable of modifications in various respects, all without departing from the invention. Accordingly, the drawings and the description are to be regarded as illustrative in nature, and not as restrictive.

### BRIEF DESCRIPTION OF THE DRAWINGS

For the purpose of illustrating the invention, the drawings show a form of the invention which is presently preferred. However, it should be understood that this invention is not limited to the precise arrangements and instrumentalities shown in the drawings.

FIG. 1 is an exploded isometric view of an embodiment of the present invention.

FIG. 2 is a sectional view of a portion of the present invention illustrating the mounting of a portion of a speaker.

FIG. 3 is an isometric view of the speaker system of the present invention as mounted in a wall structure.

FIG. 4 are plan views of five different wall sections used to form the cabinet according to one embodiment of the present invention.

### DETAILED DESCRIPTION OF THE DRAWINGS

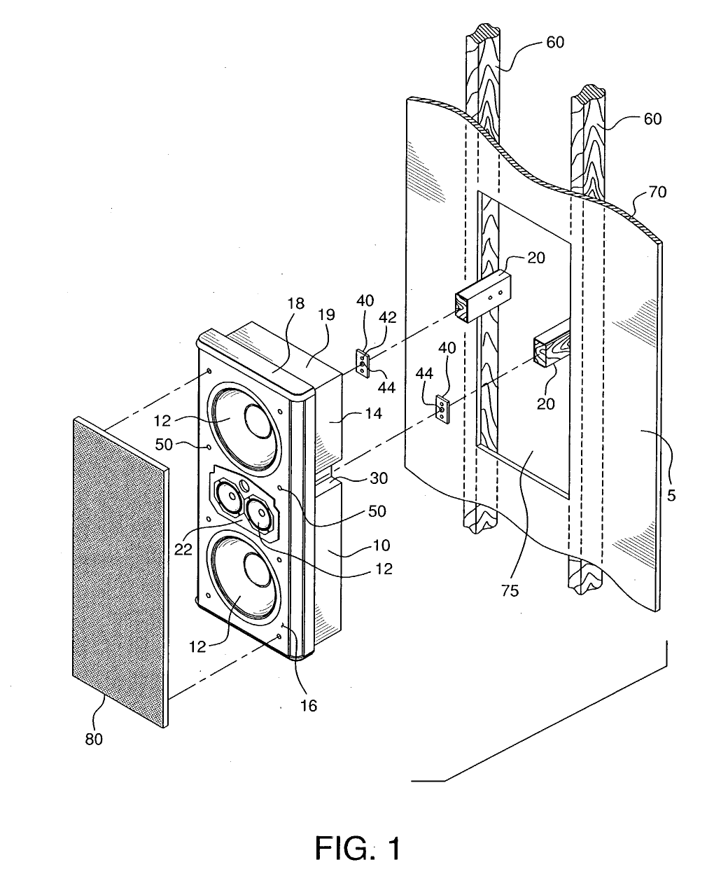

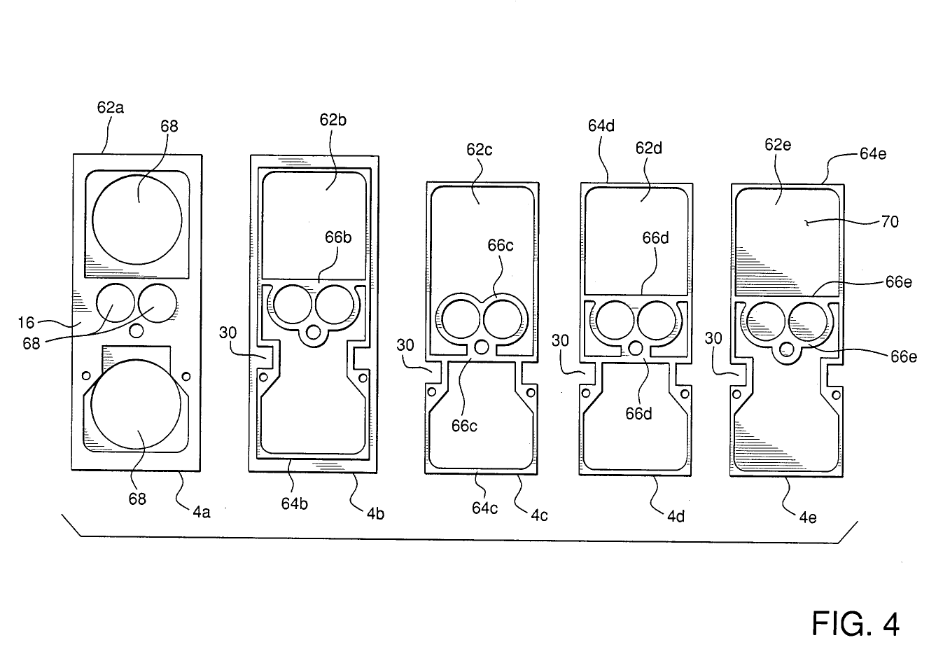

Referring to the figures, wherein like characters refer to like elements, FIG. 1 depicts an exploded isometric view of one embodiment of the loud speaker arrangement of the present invention as it is intended to be mounted into a wall structure 5. The speaker arrangement includes a speaker cabinet or enclosure 10. The cabinet 10 includes a front panel or baffle 18 and a body 19. The front panel 18 includes a plurality of cut-outs (shown in FIG. 4a) for receiving speakers 12. The speakers are attached to the front panel 18 in any conventional manner. The body 19 includes a plurality of internal chambers which preferably substantially acoustically separate some or all of the speakers from one another. As will be discussed in more detail below, the front panel 18 supports is attached to the body The body 19 has slots or grooves 30 formed on opposite sides 14 of the cabinet 10. (Only one slot is shown in the figure. However, a second identical slot 30 is formed on the opposite side 14 of the enclosure 30.) As will be discussed in more detail hereinafter, the slots 30 are configured to mate with projecting rails 20 mounted to the wall structure 5. As shown, the speaker arrangement also includes one or more speakers 12 mounted in a forward facing side 16 of the enclosure 10. The front panel 18 also comprises a director 22 which serves to direct the higher frequencies in a prescribed direction, preferably away from each other.

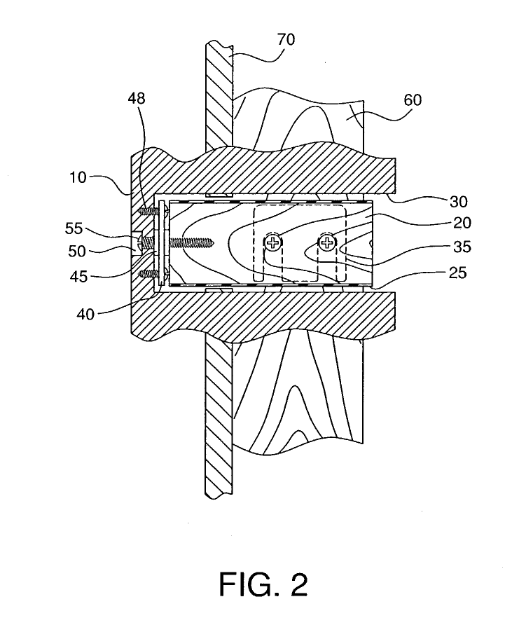

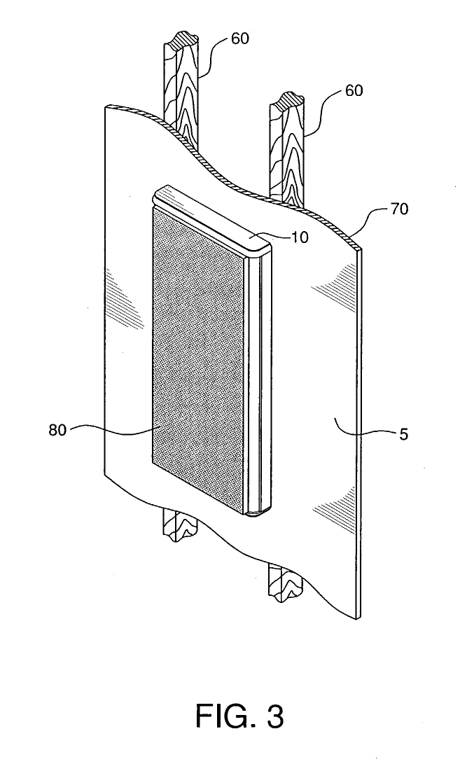

As discussed above, the speaker arrangement is intended to be mounted within an existing wall structure so as to minimally protrude as depicted in FIG. 3. FIG. 1 illustrates a section of the wall structure 5 within which the speaker arrangement is to be mounted. The wall structure 5 includes conventional framing studs 60 and wall material 70, such as sheet rock, paneling, drywall or similar wall material. Since the speaker arrangement is designed to be mounted into the wall, an opening 75 is formed in the wall material 70 with a height and width sufficiently large enough to receive the speaker body 19. The opening 75 preferably extends the width between two of the wall's framing studs 60. Current building standards define this spacing as approximately 14.5 inches from the edges of the studs. Once the opening 75 is made and framing studs 60 are exposed, the projecting rails 20 are secured to the framing studs 60, preferably at right angles to the studs. The projecting rails 20 may be secured to the framing studs 60 using any conventional attachment mechanism, such as threaded fasteners, nails, dowels, pins or rivets. The rails 20 project outward from the wall, past the wall material 70. The rails 20 and may be made from any suitable material, such as wood, plastic or metal. As shown in the figures, the rails 20 provide support for the speaker cabinet 10 and, thus, must be strong enough to support the anticipated weight of the speaker cabinet. Since the spacing between studs may vary at times, spacers 35 may be used to provide a more snug fit. As shown in FIG. 2, the spacers may be slotted to facilitate mounting of the rail 20 to the framing stud 60.

The speaker arrangement also includes reinforcing plates or brackets 40 that are designed to assist in attaching the enclosure 10 to the wall structure 5. The brackets 40 may be made of metal or any other suitable rigid material. The brackets 40 preferably include attachment holes 42 for receiving fasteners 48 (shown in FIG. 2) which attach each bracket 40 to a surface adjacent to the slot 30 of the enclosure 10. Each bracket 40 also includes a mounting hole 44 which is used to secure the enclosure 10 to the rail 20. More particularly, referring to FIG. 2, the bracket 40 is preferably secured to the back of the front panel 18 in the slot 30. The front panel 18 includes at least one aperture 50 which is formed through the front panel 18 into each slot 30. The aperture 50 is designed to receive a fastener 55 which extends though the aperture 50, the mounting hole 44 and threads into the end of the rail 20. Other types of mounting arrangements may be used for attaching the enclosure 10 to the rail 20, such as nails, dowels, or pins.

As shown in FIG. 2, the rail 20 preferably includes an outer layer 25 of vibration isolating or dampening material for attenuating the transmission of vibration from the cabinet 10 to the wall structure. This layer 25 is preferably provided on three of the rail 20, leaving the fourth side free to mount to the stud. Alternatively, the lining 25 may be attached directly to the slot or groove 30. Vibration dampening or isolating material suitable for use in the present invention includes rubber material, such as neoprene, or urethane foam. Other types of materials may be used and would be apparent to those skilled in the art in light of the teachings provided herein. It is also contemplated that the dampening material may be located between the rail and the stud, instead of between the cabinet and the rail.

In order to further minimize the transmission of vibration from the enclosure 10 to the wall structure 5, the bracket 40 preferably includes an elastomeric grommet or bushing 45 which is disposed about or in the mounting hole 44. The fastener 55 passes through the elastomeric bushing 45 and is, thus, isolated from the bracket 40.

In another embodiment (not shown), the projecting rail 20 may also include a fastener which projects outwardly from the center of the rail and which is designed to pass through the bracket 40 and the aperture 50. In this embodiment, a nut or similar attachment device would attach to the fastener to secure the enclosure to the rails. If the speakers are mounted in a public place where theft may be a concern, then the bolt may be a locking cap.

FIG. 3 depicts the enclosure 10 as it is intended to be mounted within the wall structure 5. As discussed above, the front panel 18 is designed with a sufficient size to obscure the opening in the wall structure 5 when the speaker arrangement 5 is installed. A grille cover 80 mounted to the enclosure and protects and obscures viewing of the loudspeakers.

As shown in FIGS. 4a-4e, the cabinet 10 may be formed from a plurality of stacked sections 62a-62e. The sections 62 may be made of milled (wood, composite) or extruded (polymer) material. The several of the sections 62 include an outer wall 64b-64e and interior walls 66b-66c. The outer walls 64b-64e preferably are substantially the same so that when the sections 62 are stacked on top of each other, the outer wall 64 sections define the exterior side of the body 19. At least one section 62a is formed with a front facing 16 so as to define the front panel 18. Another section includes a back facing 70 for forming the back surface of the cabinet.

The interior walls 66b-66e are formed so that when the sections 62 are stacked, the interior walls 66 define internal chambers associated with the various loudspeakers. It is preferable that the interior walls 66 substantially acoustically separate each chamber from another so as to maximize the sound performance from the cabinet. The interior walls may, however, be designed to permit sound transmission from chambers housing similar speakers. For example, it may be desirable to incorporate passages between the chambers that house the woofers to permit sound to pass between them. Since the chambers will vary in depth and size, the configuration of the interior walls 66 in the various sections 62 will differ. Also, the number of sections 62 may be varied to control the overall depth of the cabinet. This allows for a custom fit when installing a speaker into a wall opening. The sections 62 may be secured to one another using any conventional fastening mechanism, such as glue, screws, or lamination. As shown in FIG. 4, the front panel includes openings 68 for placement of loudspeakers.

The present invention may be embodied in other specific forms without departing from the spirit or essential attributes thereof and, accordingly, reference should be made to the appended claims, rather than to the foregoing specification, as indicating the scope of the invention.

What is claimed is:

1. A loudspeaker arrangement mountable within a wall structure opening comprising:
a speaker enclosure having at least one speaker mounted in it, the enclosure having spaced apart sides, and at least one slot formed in one side; and
at least one rail adapted to be mounted to a framing stud of a wall structure so as to extend outward from an opening in the structure, the rail designed to matingly engage with the at least one slot.

2. The loudspeaker arrangement of claim 1, wherein the slot has a vibration absorbing material lining disposed on at least a portion of the slot between the rail and the enclosure.

3. The loudspeaker arrangement of claim 1, wherein the rail has a vibration absorbing material covering formed on at least a portion of its surface.

4. A loudspeaker arrangement mountable within a wall structure opening comprising:
at least one loudspeaker;
at least one rail adapted to attach to a wall framing stud;
a speaker enclosure for housing the loudspeaker, the enclosure including:
a front panel having a width and height;
a body having a plurality of compartments, the body being formed from a plurality of sections stacked on one another, each section including an outer wall and at least one interior wall, the outer walls of the sections defining a height and width of the body, the height and width of the body being less than the height and width of the front panel so as to form a lip;
at least one slot formed in at least one wall of the body, the slot adapted to matingly engage with the at least one rail; and
at least one opening formed in the front panel for receiving the loudspeaker.

5. The loudspeaker arrangement of claim 4, further comprising:
a cross-over device for band pass filtering of an audio electrical signal to the loudspeakers; and
a passive isolator mounted between the enclosure and the wall structure for reducing noise transmission.

6. The loudspeaker arrangement of claim 4, further comprising a grill cover removably attachable to the enclosure for inhibiting an unfettered view of the loudspeaker.

7. The loudspeaker arrangement of claim 4, wherein there are a plurality of loudspeakers including at least one woofer speaker for providing low frequency sound reproduction.

8. The loudspeaker arrangement of claim 4, wherein there are a plurality of loudspeakers including at least one mid-range speaker for providing middle-frequency sound reproduction.

9. The loudspeaker arrangement of claim 4, wherein there are a plurality of loudspeakers including at least one tweeter speaker for providing high-frequency sound reproduction.

10. The loudspeaker arrangement of claim 4, wherein the front panel includes at least one aperture formed through the front panel into the slot, and a mounting bracket, attached to a back surface of the front panel in the slot, the mounting bracket having at least one hole formed in it, the hole being aligned with the aperture so as to permit a fastener to pass through the aperture and the hole in the mounting bracket for securing the front panel to the at least one rail.

11. The loudspeaker arrangement of claim 10 wherein the mounting bracket includes an elastomeric gasket disposed about the opening for providing noise and vibration reduction.

12. The loudspeaker arrangement of claim 10 wherein the at least one aperture includes a recessed portion, and wherein the loudspeaker arrangement further comprises a plug adapted to be removably inserted into the recessed portion for closing off the aperture.

13. The loudspeaker arrangement of claim 10 wherein there are two apertures formed in the front panel, each aperture extending into a different slot, each aperture having a mounting plate associated with it, and wherein the loudspeaker arrangement further comprises at least two fasteners adapted to be inserted into the apertures for attaching the front panel to a rail disposed within the slot.

14. A loudspeaker arrangement mountable within a wall structure opening comprising:
A plurality of loudspeakers;
two rails adapted to attach to wall framing studs;
a speaker enclosure for housing the loudspeakers, the enclosure including:
a front panel having a width and height, the front having a plurality of openings formed in it for receiving the loudspeakers; and
a body having a plurality of compartments, each compartment being associated with a speaker for creating an acoustical chamber, the body being formed from a plurality of sections which are stacked on one another, each section including an outer wall and at least one interior wall, the combination of the outer walls of the sections defining a height and width of the body, the height and width of the body being less than the height and width of the front panel so as to form a lip, at least two slots are formed in the body, the slots being formed on opposite sides of the body, each slot having a height that is slightly larger than the height of the rail so that the rail can slide within the slot.

15. A method of mounting a loudspeaker in a wall opening comprising the steps of:
cutting an opening into a wall to expose two adjacent framing studs;
attaching rails perpendicular to the framing studs so that the rails extend beyond the wall;
providing a loudspeaker enclosure having slots formed in opposed sides, the slots sized to engage the rails;
sliding the enclosure onto the rails; and
securing the enclosure to the wall by fastening it to the rails.
